(19) United States
(12) Patent Application Publication
(10) Pub. No.: US 2015/0090317 A1
(43) Pub. Date: Apr. 2, 2015

(54) SOLAR CELL, SOLAR CELL MODULE, AND METHOD FOR PRODUCING SOLAR CELL

(71) Applicant: c/o SANYO Electric Co., Ltd., Osaka (JP)

(72) Inventors: Nozomu TOKUOKA, Osaka (JP); Yoshikazu IBARA, Gifu (JP); Hiroyuki KASE, Shiga (JP); Tomoki NARITA, Osaka (JP)

(21) Appl. No.: 14/564,334

(22) Filed: Dec. 9, 2014

Related U.S. Application Data
(63) Continuation of application No. PCT/JP2012/066676, filed on Jun. 29, 2012.

(51) Int. Cl. H01L 31/0224; H01L 31/18; H01L 31/0465; H01L 27/142; H01L 31/0236; H01L 31/05

(52) U.S. Cl. CPC H01L 31/022433; H01L 31/02366; H01L 31/05; H01L 31/0465; H01L 27/142; H01L 31/18; H01L 2933/0016
USPC 136/249; 136/256; 438/98

(57) ABSTRACT

This solar cell module is provided with a plurality of solar cells, a first protective member, a second protective member, a filler, and a wiring material. The solar cells have a photoelectric conversion part, transparent conductive layers formed on a principal surface of the photoelectric conversion part, and plated electrodes of silver or copper, formed directly on the transparent conductive layers.

### CROSS-REFERENCE TO RELATED APPLICATIONS

The present application is a continuation under 35 U.S.C. §120 of PCT/JP2012/066676, filed Jun. 29, 2012, which is incorporated herein by reference.

### TECHNICAL FIELD

The present invention relates to a solar cell, a solar cell module, and a method of manufacturing a solar cell.

### BACKGROUND ART

A solar cell comprises a photoelectric conversion unit, and an electrode formed over a primary surface of the photoelectric conversion unit (for example, refer to Patent Document 1). A solar cell module comprises a plurality of solar cells, and a wiring member that is attached over the electrode of the solar cells and that connects the solar cells.

### RELATED ART REFERENCE

### Patent Document

[Patent Document 1] JP 2009-290234 A

### DISCLOSURE OF INVENTION

### Technical Problem

In a solar cell, a further improvement of the photoelectric conversion characteristic is desired. In order to improve the photoelectric conversion characteristic, for example, it is important to achieve superior contact properties between the photoelectric conversion unit and the electrode. In addition, in a solar cell module, achieving superior contact properties between the solar cell and the wiring member is also important.

### Solution to Problem

According to one aspect of the present invention, there is provided a solar cell comprising: a photoelectric conversion unit; a transparent conductive layer formed over a primary surface of the photoelectric conversion unit; and a silver or copper plated electrode formed directly over the transparent conductive layer.

According to another aspect of the present invention, there is provided a solar cell module comprising: a plurality of the solar cells; a wiring member that connects the solar cells; and an adhesive that adheres the plated electrode of the solar cell and the wiring member, and that enters into a through hole or a gap in the plated electrode and adheres the wiring member and the transparent conductive layer.

According to another aspect of the present invention, there is provided a method of manufacturing a solar cell, comprising: forming a transparent conductive layer over a primary surface of a photoelectric conversion unit; and, after applying a reduction process to at least a part of an electrode formation region, of a region over the transparent conductive layer in which a silver or copper plated electrode is formed, forming the plated electrode in the electrode formation region.

### Advantageous Effects of Invention

According to various aspects of the present invention, the photoelectric conversion efficiency of the solar cell can be improved. In addition, superior contact properties between the photoelectric conversion unit and the electrode can be achieved. According to various aspects of the present invention, superior contact properties between the solar cell and the wiring member can be achieved in the solar cell module.

### BRIEF DESCRIPTION OF DRAWINGS

FIG. 1 is a cross sectional diagram of an example solar cell module according to a preferred embodiment of the present invention.

FIG. 2 is a diagram of an example solar cell according to a preferred embodiment of the present invention, viewed from a side of a light receiving surface.

FIG. 3 is a diagram of an example solar cell according to a preferred embodiment of the present invention, viewed from a side of a back surface.

FIG. 4 is a diagram showing a part of a cross section along an A-A line of FIGS. 2 and 3.

FIG. 5 is a diagram exemplifying a behavior of light entering an example solar cell according to a preferred embodiment of the present invention.

FIG. 6 is a diagram showing an alternative configuration of a preferred embodiment exemplified in FIG. 2.

FIG. 7 is a diagram showing a part of a cross section along a D-D line of FIG. 6.

FIG. 8 is a diagram showing an alternative configuration of the embodiment exemplified in FIG. 3.

FIG. 9 is a diagram showing a part of a cross section along an E-E line of FIG. 8.

FIG. 10 is a B-part enlarged diagram of FIG. 2, with drawing of a collecting electrode omitted.

FIG. 11 is a diagram showing a part of a cross section along an F1-F1 line of FIG. 10.

FIG. 12 is a diagram showing a part of a cross section along an F2-F2 line of FIG. 10.

FIG. 13 is a G-part enlarged diagram of FIG. 10.

FIG. 14 is a diagram showing an alternative configuration of the embodiment exemplified in FIG. 10.

FIG. 15 is a diagram showing another alternative configuration of the embodiment exemplified in FIG. 10.

FIG. 16 is a diagram showing a part of a cross section along an H-H line of FIG. 15.

FIG. 17 is a C-part enlarged diagram of FIG. 3, with drawing of a collecting electrode omitted.

FIG. 18 is a diagram showing an alternative configuration of the embodiment exemplified in FIG. 17.

FIG. 19 is a diagram showing an alternative configuration of an example photoelectric conversion unit according to a preferred embodiment of the present invention.

FIG. 20 is a diagram showing an alternative configuration of an example photoelectric conversion unit according to a preferred embodiment of the present invention.

FIG. 21 is a diagram for explaining an example method of manufacturing a solar cell according to a preferred embodiment of the present invention.

FIG. 22 is a diagram for explaining an example method of manufacturing a solar cell according to a preferred embodiment of the present invention.

FIG. 23 is a diagram for explaining an example method of manufacturing a solar cell according to a preferred embodiment of the present invention.

FIG. 24 is a diagram for explaining an example method of manufacturing a solar cell according to a preferred embodiment of the present invention.

### BEST MODE FOR CARRYING OUT THE INVENTION

A preferred embodiment of the present invention will now be described in detail with reference to the drawings. The present invention is not limited to the below-described preferred embodiment. In addition, the drawings referred to in the embodiment are schematically described, and the size and ratio of the constituent elements drawn in the drawings may differ from the actual structure. Specific size, ratio, or the like should be determined in consideration of the below description.

In the specification, a description of “a second member (for example, a transparent conductive layer) formed over a first member (for example, a primary surface of a photoelectric conversion unit) ” is not intended to describe only a case where the first and second members are formed in direct contact with each other, unless otherwise particularly stated. In other words, such a description is meant to include a case where another member exists between the first and second members.

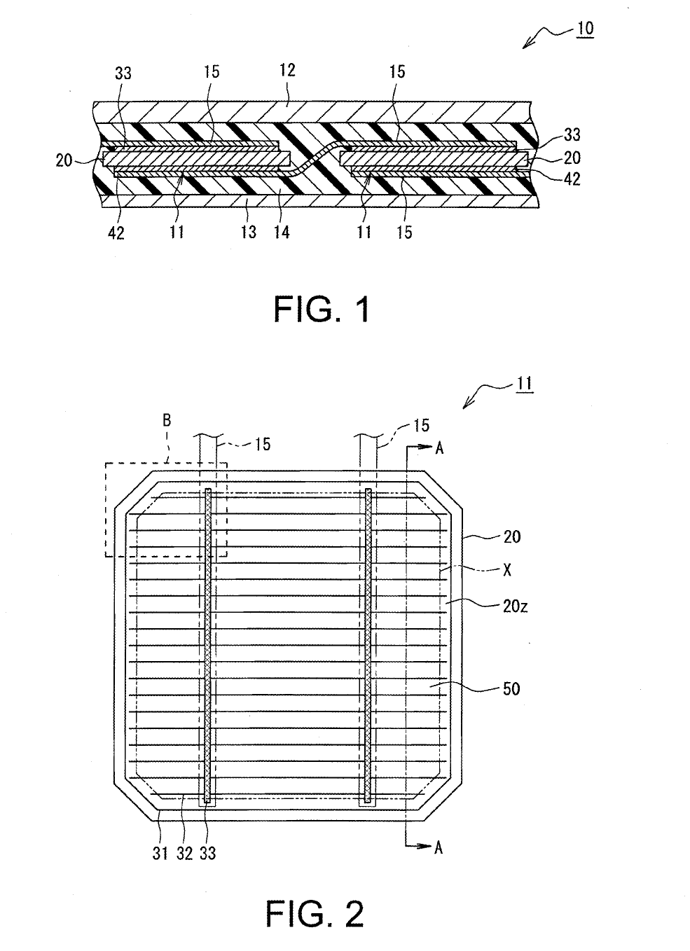

FIG. 1 is a cross sectional diagram cutting a solar cell module 10 in a thickness direction. The solar cell module 10 includes a plurality of solar cells 11, a first protection member 12 which is placed over a side of a light receiving surface of the solar cell 11, and a second protection member 13 which is placed over a side of a back surface of the solar cell 11.

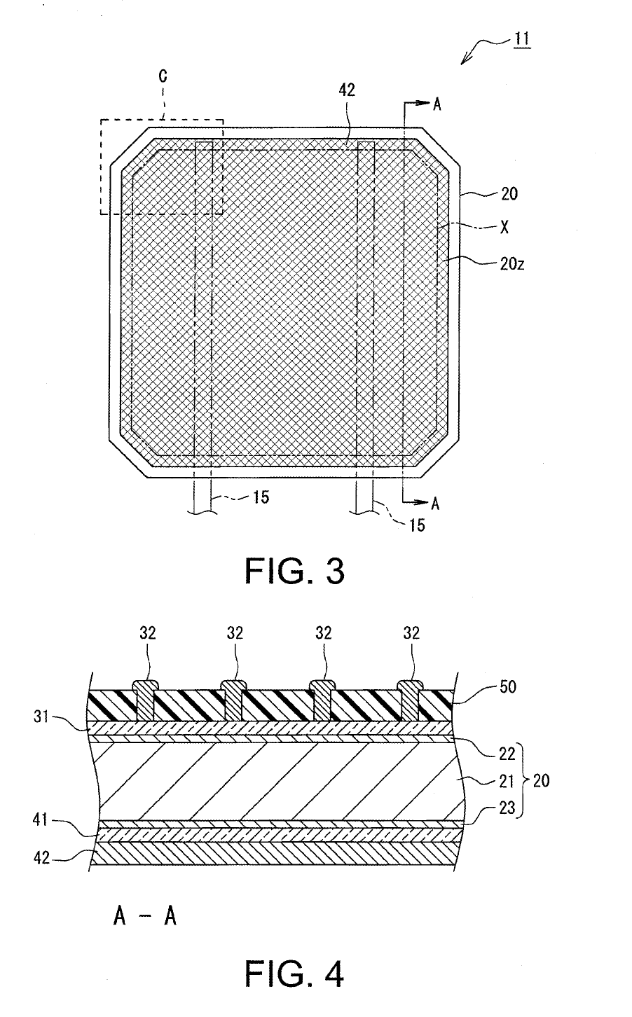

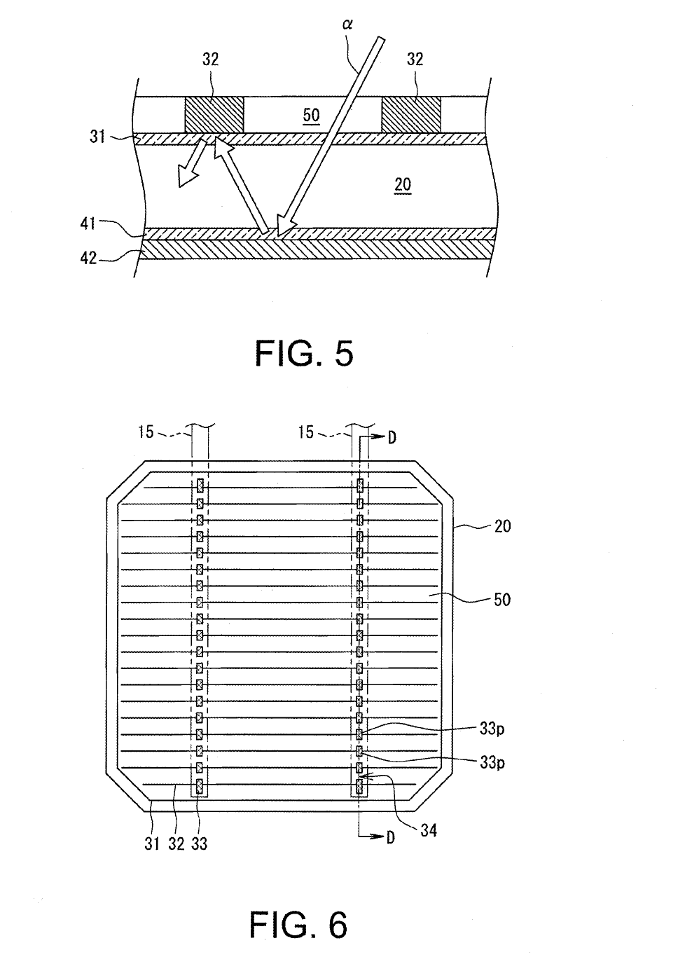

FIG. 2 is a diagram of the solar cell 11 viewed from the side of the light receiving surface. FIG. 3 is a diagram of the solar cell 11 viewed from the side of the back surface. FIG. 4 is a diagram showing a part of a cross section, of the solar cell 11, which is cut in a thickness direction along an A-A line of FIGS. 2 and 3. FIG. 5 is a diagram simplifying FIG. 4, and exemplifying a behavior of light α entering the solar cell 11. An electrode structure of the solar cell 11 of FIG. 1 is shown in a simplified manner from an electrode structure of FIG. 2 or the like, and only a bus bar portion 33 and a metal layer 42 are shown.

The solar cell 11 includes a photoelectric conversion unit that receives solar light and that produces carriers, a transparent conductive layer 31 formed over a light receiving surface of the photoelectric conversion unit 20, a finger portion 32, the bus bar portion 33, and an insulating coating layer 50 formed over the transparent conductive layer 31, a transparent conductive layer 41 formed over aback surface of the photoelectric conversion unit 20, and the metal layer 42 formed over the transparent conductive layer 41. In the solar cell 11, carriers produced in the photoelectric conversion unit 20 are collected by the finger portion 32, the bus bar portion 33, and the metal layer 42. Here, a “light receiving surface” refers to a primary surface through which the solar light primarily enters from the outside of the solar cell, and a “back surface” refers to a primary surface on a side opposite from the light receiving surface. For example, of the solar light entering the solar cell 11, 50%˜100% enters the solar cell 11 from the side of the light receiving surface.

The plurality of solar cells 11 are sandwiched by the first protection member 12 and the second protection member 13, and are sealed by an encapsulant 14. For the first protection member 12 and the second protection member 13, for example, a member having a light transmissive characteristic such as a glass substrate, a resin substrate, a resin film, or the like may be used. For the encapsulant 14, for example, a resin such as ethylene vinyl acetate copolymer (EVA) or the like may be used.

The solar cell module 10 includes a wiring member 15 that connects the plurality of solar cells 11 in series. The wiring member 15 is bent in the thickness direction of the solar cell module 10 between the solar cells 11 placed adjacent to each other, and connects the solar cells 11 in series. The wiring member 15 is attached on the bus bar portion 33 and the metal layer 42 of the solar cell 11 using an adhesive 16. For the adhesive 16, for example, a thermosetting adhesive in which, for example, curing agent is mixed as necessary to an epoxy resin, an acrylic resin, a urethane resin, or the like, is preferably used. In the resin, a conductive filler such as Ag particles may be included, but from the viewpoint of the manufacturing cost and reduction of light blockage loss, a non-conductive thermosetting adhesive is preferable. As a form of the adhesive 16, for example, a film form and a paste form can be exemplified.

The photoelectric conversion unit 20 includes a substrate 21 made of a semiconductor material such as a crystalline silicon (c-Si), gallium arsenide (GaAs), indium phosphide (InP), or the like, an amorphous semiconductor layer 22 formed over the light receiving surface of the substrate 21, and an amorphous semiconductor layer 23 formed over the back surface of the substrate 21. The amorphous semiconductor layers 22 and 23 are formed, for example, over the entire region of the primary surface of the substrate 21. The substrate 21 may be, for example, an n-type monocrystalline silicon substrate. On the light receiving surface and the back surface of the substrate 21, a texture structure (not shown) is preferably formed. The texture structure is an unevenness structure for reducing reflection of light, and has, for example, an unevenness size (diameter of circumscribing circle in a two-dimensional microscopic image) of about 1 μm˜10 μm.

The amorphous semiconductor layer 22 has, for example, a layered structure in which an i-type amorphous silicon layer and a p-type amorphous silicon layer are layered in that order from the side of the substrate 21. The amorphous semiconductor layer 23 has, for example, a layered structure in which an i-type amorphous silicon layer and an n-type amorphous silicon layer are layered in that order from the side of the substrate 21. The photoelectric conversion unit 20 may have a structure in which an i-type amorphous silicon layer and an n-type amorphous silicon layer are formed in that order over the light receiving surface of the substrate 21, and an i-type amorphous silicon layer and a p-type amorphous silicon layer are formed in that order over the back surface of the substrate 21.

The transparent conductive layer 31 is formed over the light receiving surface of the photoelectric conversion unit 20. The transparent conductive layer 31 is formed, for example, from a transparent conductive oxide (hereinafter referred to as “TCO”) in which a metal oxide such as indium oxide (In₂O₃) and zinc oxide (ZnO) is doped with tin (Sn), antimony (Sb), or the like. The transparent conductive layer 31 may be formed covering the entire region over the amorphous semiconductor layer 22, and in the configuration shown in FIGS. 2 and 3, the transparent conductive layer 21 is formed covering the entire region other than a region near the end over the amorphous semiconductor layer 22. A thickness of the transparent conductive layer 31 is preferably about 30 nm˜500 nm, and more preferably, about 50 nm˜200 nm.

A plurality (for example, 50) of the finger portions 32 are formed over the transparent conductive layer 31. The finger portion 32 is a narrow, line-shaped electrode formed over a wide area over the transparent conductive layer 31. A plurality (for example, two) of the bus bar portions 33 extend in a direction intersecting the finger portion 32. The bus bar portion 33 is an electrode which collects the carriers from the finger portions 32, and in the solar cell module 10 the wiring member 15 is attached to the bus bar portion 33. The wiring member 15 preferably has a wider width than the bus bar portion 33, and is preferably connected to the finger portion 32 on both sides in the width direction of the bus bar portion 33.

The bus bar portions 33 are placed approximately parallel to each other with a predetermined spacing therebetween, and the plurality of finger portions 32 are placed approximately perpendicular to the bus bar portions 33. A part of each of the plurality of finger portions 32 extends to an end edge 20z at a side that is further out than a virtual line X of the light receiving surface from each of the bus bar portions 33, and a remaining part of each of the plurality of finger portions 32 connects the bus bar portions 33. The bus bar portions 33 also extend to the end edge 20z of the light receiving surface.

The coating layer 50 is an insulating layer formed over the transparent conductive layer 31. The coating layer 50 is preferably formed over the entire region over the transparent conductive layer 31 other than the region where the collecting electrode is formed. A thickness of the coating layer 50 is, for example, 20 μm˜30 μm. The thickness of the coating layer 50 is preferably approximately the same as the thickness of the collecting electrode, but may be slightly thinner or thicker than the thickness of the collecting electrode. A material forming the coating layer 50 is preferably a thermosetting resin including an epoxy resin or the like, from the viewpoint of productivity, insulating characteristics, contact properties with the encapsulant 14, or the like.

The transparent conductive layer 41 is formed over the back surface of the photoelectric conversion unit 20. The other structures of the transparent conductive layer 41 are similar to those of the transparent conductive layer 31. The metal layer 42 functions as a collecting electrode that collects the carriers via the transparent conductive layer 41, and the wiring member 15 is attached thereon. The metal layer 42 is preferably formed over approximately the entire region of the transparent conductive layer 41 (a range that can be assumed to be substantially the entire region, for example, a region of greater than or equal to 95% over the transparent conductive layer 41). Alternatively, the bus bar portion may be formed over the metal layer 42, or the metal layer 42 may be changed to the finger portion.

The finger portion 32 and the bus bar portion 33 are preferably plated electrodes formed by plating. In the following description, unless otherwise particularly stated, the collecting electrode is a plated electrode. The plated electrode maybe formed, for example, by electroplating. The plated electrode is formed by a metal such as, for example, nickel (Ni), copper (Cu), and silver (Ag). As such a metal, Ag or Cu is preferable from the viewpoint of conductivity and reflection characteristic of light or the like, and Cu is more preferable in consideration of the manufacturing cost.

The plated electrode may have a layered structure with a plurality of metal layers (for example, a first layer of a Ni layer and a second layer of a Cu layer), but preferably has a single layer structure of Ag or Cu, particularly, the single layer structure of Cu. The single layer structure of Cu includes a layer formed by a Cu diffusion prevention layer and a Cu plated electrode. The Ag plated electrode and the Cu plated electrode are preferably formed directly over the transparent conductive layers 31 and 41. In other words, no other layer is provided between the Ag plated electrode and the Cu plated electrode and the transparent conductive layers 31 and 41. Cu has a particularly high reflectance for light of a wavelength in a long wavelength region (for example, greater than or equal to 600 nm), and has a reflectance with respect to light of 600 nm of, for example, about 1.5 times that of Ni.

In the present embodiment, about 100% of the light enters from the side of the light receiving surface of the photoelectric conversion unit 20. As shown in FIG. 5, a part of the light a entering from between the finger portions 32 into the photoelectric conversion unit 20 is absorbed by the photoelectric conversion unit 20, and the remaining part transmits through the photoelectric conversion unit 20 and the transparent conductive layer 41 and is reflected by the metal layer 42. This primary reflection light propagates in the photoelectric conversion unit 20 toward the side of the light receiving surface, and a part thereof is again reflected by the finger portion 32 (secondary reflection), and propagates in the photoelectric conversion unit 20 toward the side of the back surface. As a result of the reflection of the light α, the light collection efficiency of the photoelectric conversion unit 20 can be improved. In particular, by forming the Ag or Cu plated electrode having a superior reflection characteristic directly over the transparent conductive layers 31 and 41, it becomes possible to reduce the amount of absorption of the light a at the surface of the plated electrode, and to further improve the light collection efficiency.

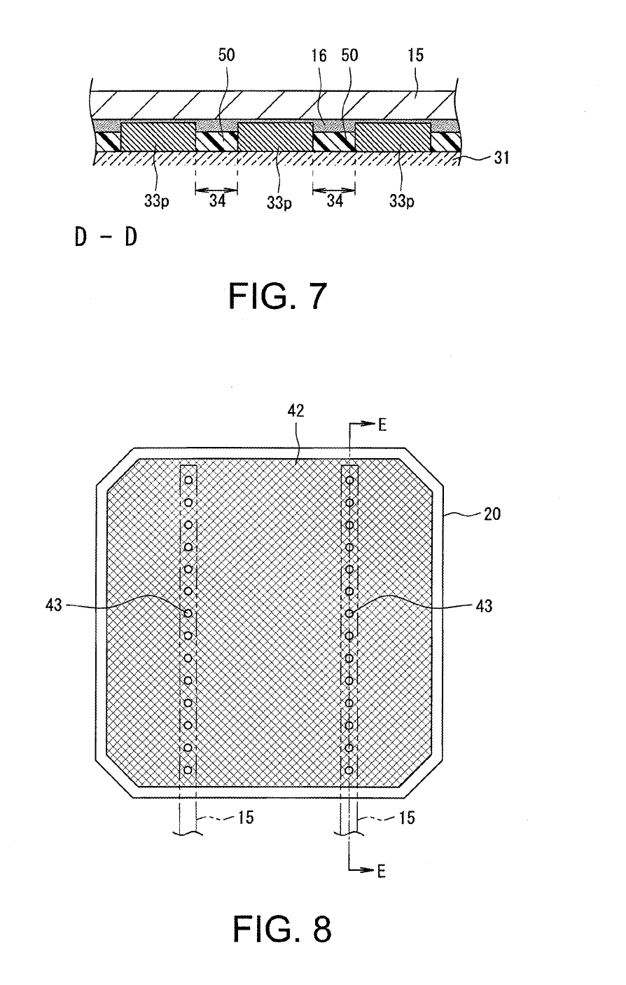

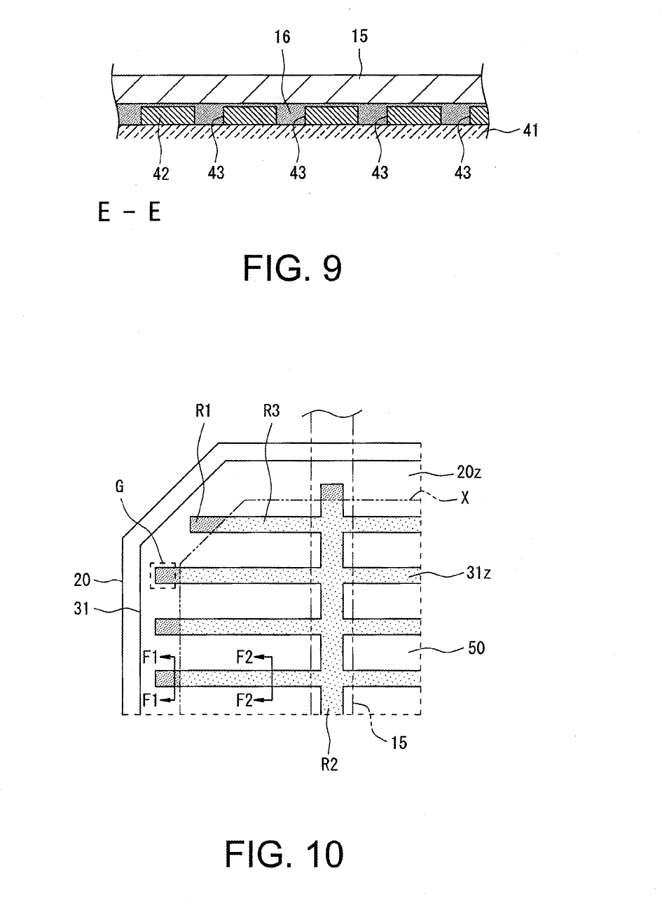

FIGS. 6-9 show another configuration of the collecting electrode. FIG. 6 is a diagram corresponding to FIG. 2, and FIG. 7 is a diagram showing a part of a cross section along a D-D line of FIG. 6. FIG. 8 is a diagram corresponding to FIG. 3, and FIG. 9 is a diagram showing a part of a cross section along an E-E line of FIG. 8. FIGS. 7 and 9 show a state where the wiring member 15 is attached.

The bus bar portion 33 shown in FIGS. 6 and 7 is formed by a plurality of portions 33p (hereinafter referred to as a “block 33p”) arranged in a line form. A gap 34 for separating the adjacent blocks 33p is formed between the blocks 33p. The coating layer 50 is provided in the gap 34. A shape, placement, size, or the like of the block 33p can be arbitrarily adjusted according to a formation pattern of the coating layer 50, as will be described later.

The plurality of blocks 33p are provided, for example, in a straight line shape along a longitudinal direction of the wiring member 15. As described above, the wiring member 15 is attached to the block 33p using the adhesive 16. The adhesive 16 preferably adheres the wiring member 15 and the finger portion 32 on both sides in the width direction of the bus bar portion 33, and more preferably, enters the gap 34 and adheres the wiring member 15 and the coating layer 50. With such a configuration, in the gap 34, the adhesive 16 adheres the wiring member 15 and the transparent conductive layer 31 with the coating layer 50 therebetween. Because contact properties between the adhesive 16 and the coating layer 50 and contact properties between the coating layer 50 and the transparent conductive layer 31 are superior compared to the contact properties between the plated electrode and the transparent conductive layer 31, with the provision of the gap 34, the contact strength between the wiring member 15 and the solar cell 11 can be improved.

The coating layer 50 need not be present in the gap 34. In this case, the adhesive 16 enters the gap 34 and is attached to the transparent conductive layer 31, to adhere the wiring member 15 and the transparent conductive layer 31. Because the contact properties between the adhesive 16 and the transparent conductive layer 31 is superior compared to the contact properties between the plated electrode and the transparent conductive layer 31, in this case also, the contact strength between the wiring member 15 and the solar cell 11 can be improved. Stress tends to be easily applied from the wiring member 15 to the bus bar portion 33, but with the presence of the gap 34, peeling at the boundary between the bus bar portion 33 and the transparent conductive layer 31 can be sufficiently inhibited.

The metal layer 42 shown in FIGS. 8 and 9 has a through hole 43 in an area where the wiring member 15 is attached. The through hole 43 is a hole penetrating through the metal layer 42 in the thickness direction, and the transparent conductive layer 41 is exposed by the through hole 43. A plurality of the through holes 43 are preferably formed along a longitudinal direction of the area where the wiring member 15 is attached. The plurality of through holes 43 are formed, for example, from one end to the other end of the area with an equal spacing between them. The shape, placement, size, or the like of the through hole 43 can be arbitrarily adjusted by a shape and attachment method of an electroplating probe 110 or the like, as will be described below.

The adhesive 16 preferably enters the through hole 43 so that the adhesive 16 attaches to the transparent conductive layer 41. The adhesive 16 is provided between the wiring member 15 and the metal layer 42, a part thereof adheres the wiring member 15 and the metal layer 42, and another part enters the through hole 43 and adheres the wiring member 15 and the transparent conductive layer 41. As described above, as the contact properties with respect to the transparent conductive layer 41 are such that (adhesive 16>metal layer 42), with the provision of the through hole 43, the contact strength between the wiring member 15 and the solar cell 11 can be improved.

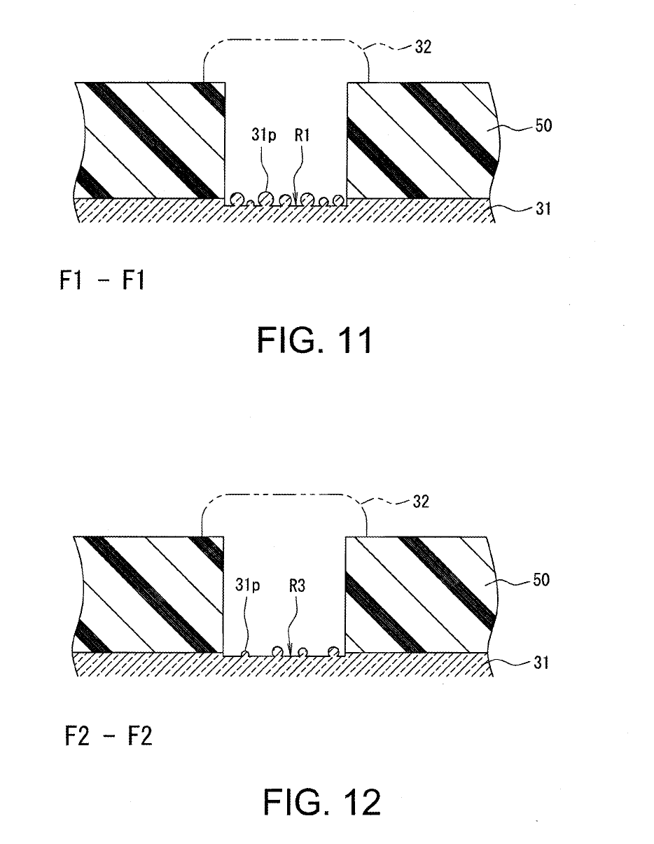

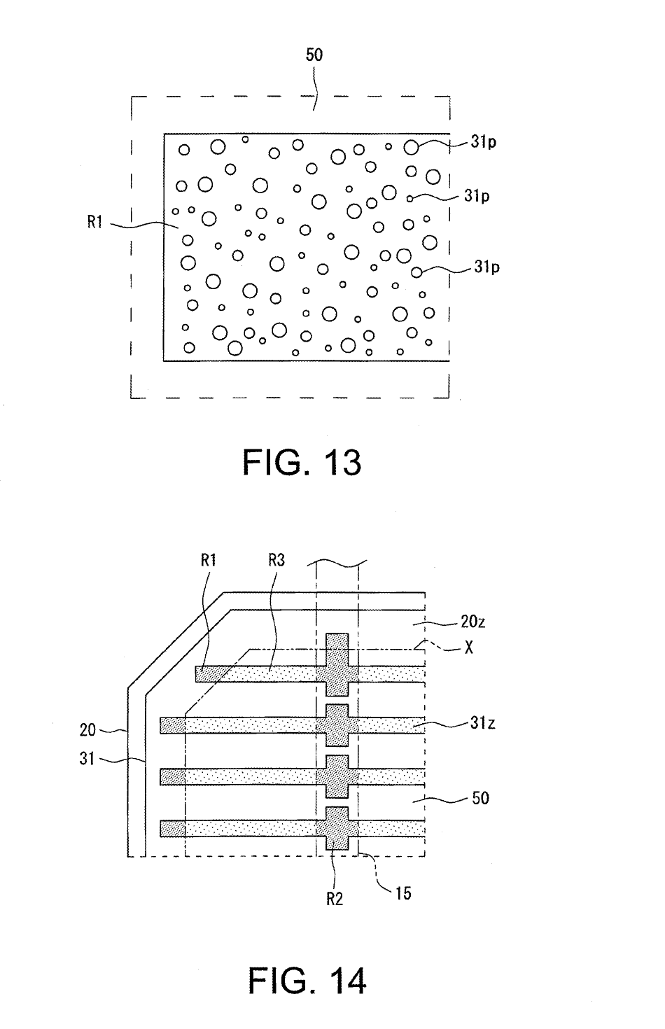

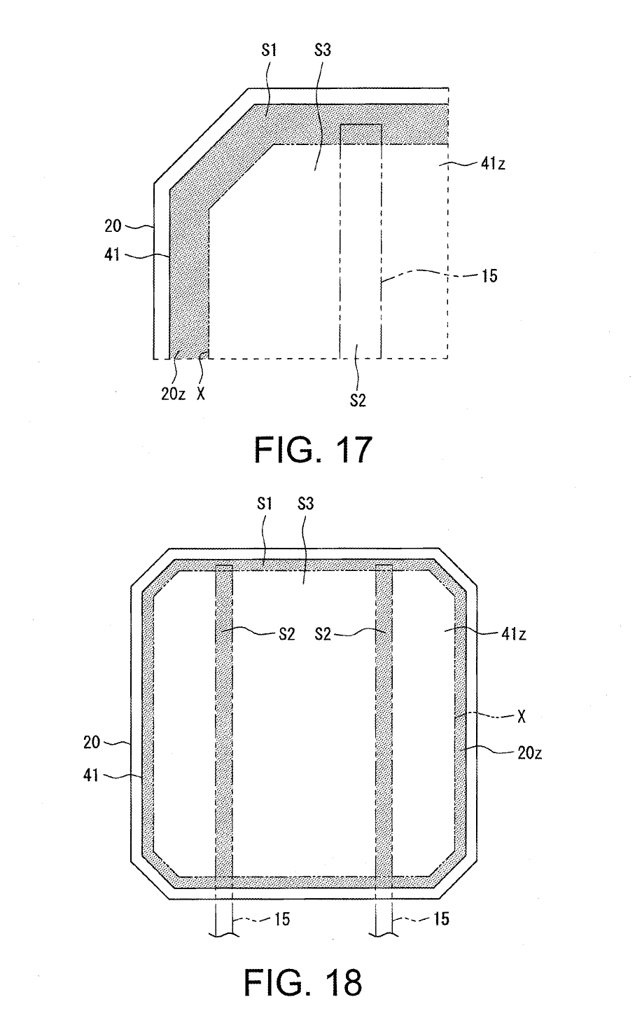

Next, a structure of the transparent conductive layers 31 and 41 will be described in detail with reference to FIGS. 10-18. FIG. 10 is a B-part enlarged diagram of FIG. 2, and is a diagram in which the collecting electrode is omitted. FIG. 11 shows a part of a cross section along an F1-F1 line of FIG. 10, FIG. 12 shows a part of a cross section along an F2-F2 line of FIG. 10, and FIG. 13 is a G-part enlarged diagram of FIG. 10. FIGS. 14-16 show an alternative configuration of the embodiment shown in FIG. 10. FIG. 17 is a C-part enlarged diagram of FIG. 3, and is a diagram in which the collecting electrode is omitted. FIG. 18 shows an alternative configuration of the embodiment shown in FIG. 17.

In the transparent conductive layer 31, preferably, in at least apart of an electrode formation region 31z in which the plated electrode is formed, a surface roughness is greater than a non-electrode formation region which is a region outside of the electrode formation region 31z. In other words, in at least a part of the electrode formation region 31z, the extent of the surface unevenness is greater than in the non-electrode formation region. The size of the surface unevenness is smaller than the texture structure size, and is preferably less than or equal to 1/10 of the texture structure size. By setting the surface roughness in the electrode formation region 31z to be greater, the contact area between the plated electrode and the transparent conductive layer 31 is increased and the contact properties therebetween can be improved. On the other hand, in the non-electrode formation region in which the solar light is received, from the viewpoint of reduction of light blockage loss or the like, the surface unevenness is preferably small and a protrusion 31p to be described later preferably does not exist. In the present embodiment, the electrode formation region 31z is a region, of the surface of the transparent conductive layer 31, not covered by the coating layer 50, and the non-electrode formation region is a region covered by the coating layer 50.

The above-described surface roughness can be evaluated by an arithmetic average roughness Ra. The arithmetic average roughness Ra can be measured, for example, using a scanning electron microscope (SEM), a laser microscope, or the like.

In the example configuration shown in FIG. 10, in the entire region of the electrode formation region 31z, the surface roughness is greater than that in the non-electrode formation region. For the electrode formation region 31z, in a region positioned at the end edge 20z of the light receiving surface, the surface roughness is greater than that at a region positioned at a center section of the light receiving surface. In the region having a greater surface roughness, for example, the thickness of the transparent conductive layer 31 becomes thinner (refer to FIG. 11), and a fill factor (FF) tends to be reduced. In addition, the light transmitting through a region with a greater surface roughness tends to be more easily attenuated and the reflectance of the incident light in the photoelectric conversion unit 20 tends to be reduced. Therefore, in order to improve the contact properties between the plated electrode and the transparent conductive layer 31 without reducing the FF and reflectance, it is preferable to selectively set the surface roughness to be greater in the end edge 20z, for example, in a range of about 10% of a length of one side of the light receiving surface from the end of the light receiving surface.

In the following, a region of the electrode formation region 31z positioned at the end edge 20z will be described as “a region R1”, a region of the electrode formation region 31 corresponding to an area in which the wiring member 15 is attached will be described as “a region R2”, and a region of the electrode formation region 31z other than R1 and R2 will be described as “a region R3”. Similarly, a region of the electrode formation region 41z positioned at the end edge 20z will be described as “a region S1”, a region of the electrode formation region 41z corresponding to an area in which the wiring member 15 is attached will be described as “a region S2”, and a region of the electrode formation region 41z other than S1 and S2 will be described as “a region S3”.

The transparent conductive layer 31 has, for example, a greater surface roughness in the region R1 than in the regions R2 and R3. In the present embodiment, because the plated electrode is formed extending to the end edge 20z, the region R1 is a region positioned at an end in the longitudinal direction of the plated electrode. In other words, for the electrode formation region 31z, at the region positioned at the end in the longitudinal direction of the plated electrode, the surface roughness is greater than a region positioned at a center section in the longitudinal direction of the plated electrode. Because boundary peeling between the plated electrode and the transparent conductive layer 31 tends to occur more at the end than the center section in the longitudinal direction of the electrode, with such a structure, the peeling can be sufficiently inhibited.

As shown in FIGS. 11-13, in the electrode formation region 31z, a plurality of protrusions 31p are formed. The protrusion 31p has, for example, a dome shape, a semispherical shape, a spherical shape, or a spindle shape, and may be considered as a particulate protrusion or particles. In the electrode formation region 31z, the surface roughness is set greater by the presence of the protrusion 31p. As will be described in detail later, the protrusion 31p is formed by reducing the TCO forming the transparent conductive layer 31. The composition of the protrusion 31p is, for example, when the TCO is a metal oxide having the primary composition of indium oxide (In₂O₃), In-rich indium oxide compared to the In₂O₃ forming the non-electrode formation region, or In.

In the present embodiment, in the region R1, a number of the protrusions 31p is greater than that in the region R3, and the size of the protrusions 31p is also greater (refer to FIGS. 11 and 12). Thus, the arithmetic average roughness Ra is in a relationship of (region R1>region R3). The thickness of the transparent conductive layer 31 is (region R1<region R3). The point of change of the surface roughness does not need to be clear, and for example, a configuration may be employed in which the surface roughness is reduced in the region R1 toward the region R3, and the surface roughness is increased in the region R3 toward the region R1. In the region R3, the surface roughness is reduced as the distance from the region R1 is increased, and the surface roughness may be of the same extent as that of the non-electrode formation region in the center section of the light receiving surface.

In an example configuration shown in FIG. 13, in the region R1, the protrusions 31p are uniformly present. In other words, the density of the protrusions 31p is similar over the entire region of the region R1. The density of the protrusions 31p refers to a ratio of an area in which the protrusions 31p exist to the entire area of the region R1, and can be measured using SEM or the like. The density of the protrusions 31p in the region R1 is preferably 10%˜100%, more preferably 20%˜80%, and particularly preferably 25%˜75%, in view of the prevention of the peeling of the plated electrode.

The size of the protrusions 31p is preferably greater than or equal to 10 nm and less than or equal to 200 nm, and more preferably, greater than or equal to 10 nm and less than or equal to 100 nm. The size of the protrusions 31p is defined as a diameter of a circumscribing circle of a protrusion 31p in a two-dimensional microscopic image such as the SEM.

FIG. 14 shows an example of the electrode formation region 31z corresponding to the embodiment in which the gap 34 is formed (refer to FIG. 6). In the example structure of FIG. 14, of the electrode formation region 31z, the surface roughness is greater in the region R1 and the region R2 than in the region R3. The regions R1 and R2 may have similar extent of surface roughness, or one of the regions may have a greater surface roughness. According to such a structure, the peeling at the end in the longitudinal direction of the plated electrode and the peeling at a portion where the stress from the wiring member 15 is applied can be sufficiently inhibited.

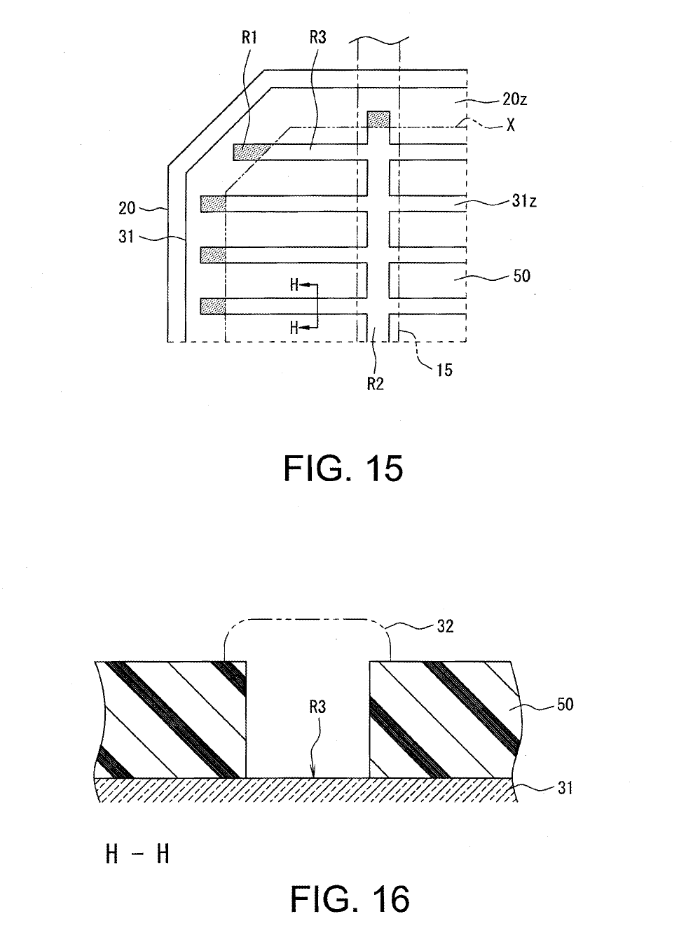

In an example configuration of FIG. 15, the surface roughness in the regions R2 and R3 is similar to the surface roughness of the non-electrode formation region, and the surface roughness is greater only in the region R1. As shown in FIG. 16 (a cross sectional diagram along an H-H line of FIG. 15), in the region R3, no protrusion 31p is formed, and the protrusion 31p is selectively formed only in the region R1. In other words, the extent of surface roughness rapidly changes at the boundary position between the region R1 and the region R3.By selectively forming the protrusion 31p only in the region R1, a superior photoelectric conversion characteristic and a superior peeling inhibition function for the plated electrode can both be efficiently achieved.

On the back surface side of the solar cell 11, the metal layer 42 is formed over an approximately entire region of the surface of the transparent conductive layer 41. In the transparent conductive layer 41, protrusions similar to the protrusions 31p may be formed over the entire region of the electrode formation region 41z (a region where the metal layer 42 is formed), that is, approximately the enter region of the surface of the transparent conductive layer 41. Preferably, similar to the electrode formation region 31z, the surface roughness of a part of the electrode formation region 41z is set greater than that in the other parts.

In a configuration shown in FIG. 17, of the electrode formation region 41z, in the region S1 positioned in the end edge 20z, the surface roughness is set greater than that in the region positioned in the center section. More specifically, the surface roughness is locally set great at the region S1. In other words, protrusions of a size greater than or equal to 10 nm and less than or equal to 200 nm are formed only in the region S1, and no protrusion is formed in the regions S2 and S3. With such a configuration, the peeling of the plated electrode can be efficiently inhibited while not reducing the FF and the reflectance.

In a configuration shown in FIG. 18, of the electrode formation region 41z, in the region S1 and the region S2, the surface roughness is set greater than that in the other region S3. In other words, the protrusions of a size of greater than or equal to 10 nm and less than or equal to 200 nm are formed only in the region S1 and the region S2. With such a configuration, the contact properties between the plated electrode and the transparent conductive layer 41 can be improved in the region R2 in which the stress due to the wiring member 15 is applied.

The transparent conductive layer 31 has, for example, a higher sheet resistance corresponding to the electrode formation region 31z than a sheet resistance corresponding to the non-electrode formation region. In particular, the sheet resistance tends to be higher as the surface roughness becomes greater, and the sheet resistance of the region R1 is, for example, about 1.05 times to 5 times the sheet resistance of the non-electrode formation region. The sheet resistance can be measured by a known method (for example, a four-point probe method). In addition, in the transparent conductive layer 31, for example, a portion immediately below the electrode formation region 31z has a non-columnar crystalline structure, and the other portions have a columnar crystalline structure. The columnar crystalline layer refers to a layer in which crystal grain boundaries oriented in the same direction can be confirmed on approximately the entire region of an observation cross section by a cross-sectional observation using the SEM. In the SEM image, dark/light portions of the contrast are repeated in one direction, which appears to be a plurality of columns arranged in the one direction. Alternatively, the image may appear to be a banded shape. The boundary of the dark/light portions of the contract shows the crystal grain boundary. The non-columnar crystalline layer is a layer in which a percentage of crystal grain boundaries oriented in different directions is larger than a percentage of crystal grain boundaries oriented in the same direction, in the cross-sectional observation using the SEM. In the SEM image, a portion in which the dark/light portions of the contrast are repeated in one direction is less than 50%, and in some cases, the portion in which the dark/light portions of the contrast are regularly repeated cannot be observed.

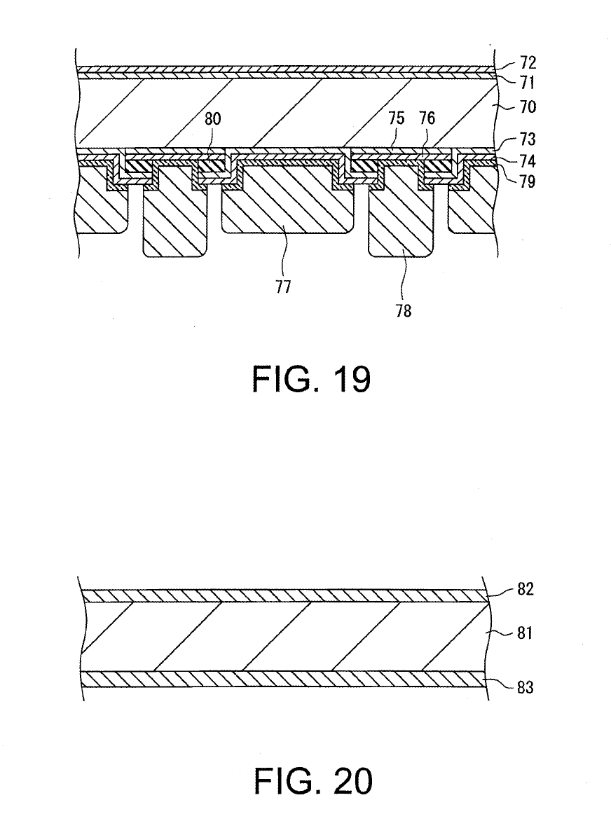

The structure of the photoelectric conversion unit may be suitably changed to a structure other than that described above. For example, as shown in FIG. 19, the photoelectric conversion unit may have a structure in which an i-type amorphous silicon layer 71 and an n-type amorphous silicon film 72 are formed over the light receiving surface side of an n-type monocrystalline silicon substrate 70, and a p-type region having an i-type amorphous silicon layer 73 and a p-type amorphous silicon layer 74 and an n-type region having an i-type amorphous silicon layer 75 and an n-type amorphous silicon layer 76 are formed over the back surface side of the n-type monocrystalline silicon substrate 70. In this case, the electrodes are provided only over the back surface side of n-type monocrystalline silicon substrate 70. The electrodes include a p-side collecting electrode 77 formed over the p-type region, and an n-side collecting electrode 78 formed over the n-type region. A transparent conductive layer 79 is formed between the p-type region and the p-side collecting electrode 77, and between the n-type region and the n-side collecting electrode 78. An insulating layer 80 is formed between the p-type region and the n-type region. Alternatively, as shown in FIG. 20, the photoelectric conversion unit may have a structure having a p-type polycrystalline silicon substrate 81, an n-type diffusion layer formed over a light receiving surface side of the p-type polycrystalline silicon substrate 81, and an aluminum metal film 83 formed over aback surface of the p-type polycrystalline silicon substrate 81.

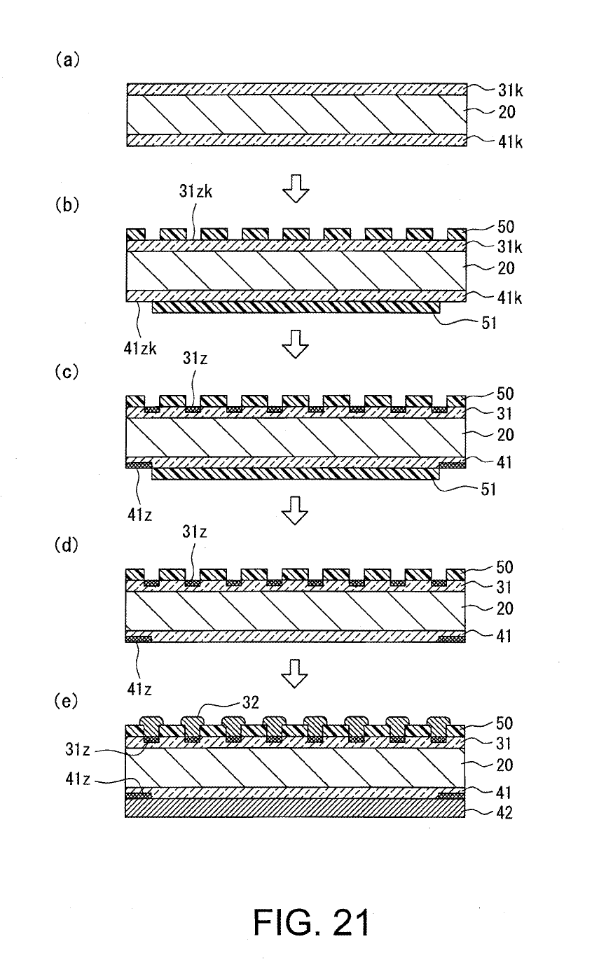

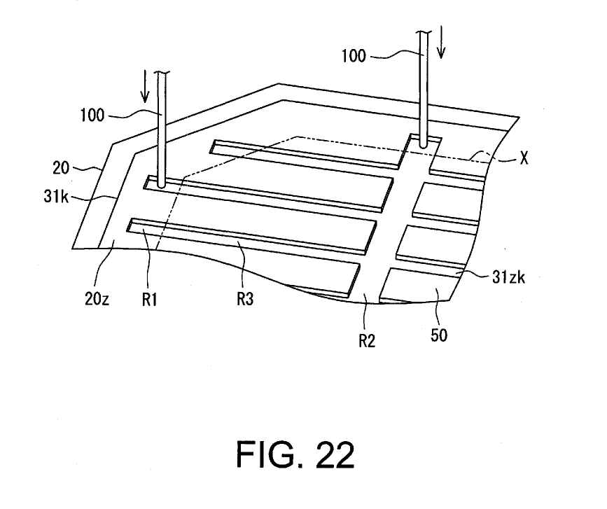

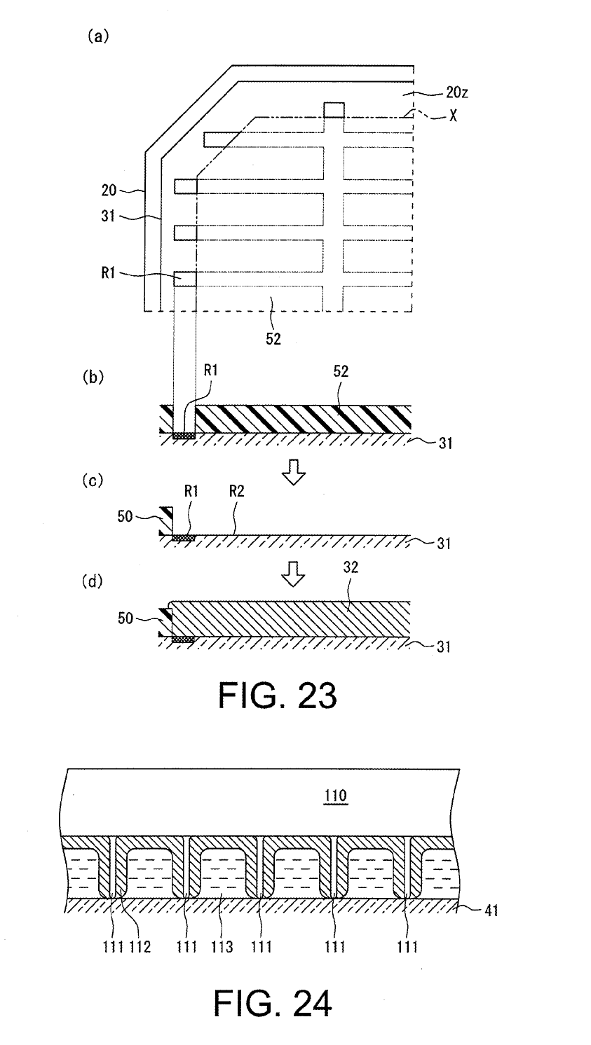

Next, a manufacturing process of the solar cell 11 having the above-described structure will be described in detail with reference to FIGS. 21-24. FIG. 21 is a diagram showing an example manufacturing process of the solar cell 11. In FIG. 21, a portion which is set to have a greater surface roughness by the reduction process is shown with a mesh hatching. Here, a configuration is described in which the plated electrode is formed through electroplating. FIG. 22 is a diagram for explaining the reduction process steps. FIGS. 23 and 24 are diagrams for explaining other configurations of the present manufacturing method.

In the manufacturing process of the solar cell 11, first, the photoelectric conversion unit 20 is manufactured by a known method (the manufacturing process of the photoelectric conversion unit 20 will not be described in detail). In the example configuration of FIG. 21, transparent conductive layers 31k and 41k which are precursors of the transparent conductive layers 31 and 41, respectively, are formed over the light receiving surface and the back surface of the photoelectric conversion unit, respectively (FIG. 21(a)).

The transparent conductive layers 31k and 41k can be formed, for example, through chemical vapor deposition (CVD). The film formation by CVD is preferably executed under a temperature condition of about 200° C.˜300° C., and the TCO is crystallized by the heat and the columnar crystal layer is formed. The transparent conductive layers 31k and 41k may alternatively be formed at a low temperature of less than 200° C., by sputtering. In this case, a separate annealing step is provided to crystallize the TCO. An electrical conductivity of the TCO is improved by the TCO being crystallized.

Then, coating layers 50 and 51 are respectively formed as mask patterns covering the transparent conductive layers 31k and 41k (FIG. 21(b)). The coating layer 50 formed over the transparent conductive layer 31k has a pattern to expose the entire region of an electrode formation region 31zk (electrode formation region 31z before the reduction process) and to cover the other regions, and is used as a mask in the electroplating process. The coating layer 50 also functions as a mask in the reduction process. The coating layer 51 formed over the transparent conductive layer 41k functions solely as a mask in the reduction process, and is removed before the electroplating step. The coating layer 51 has a pattern, for example, to expose the region S1 positioned at the end edge 20z of the electrode formation region 41z, and to cover the other regions.

The coating layers 50 and 51 can be formed through a known method. For example, after a thin film layer made of a photo-curing resin is formed by spin coating over the transparent conductive layers 31k and 41k, the thin film layer may be patterned using a photolithography process. Alternatively, the coating layers 50 and 51 may be formed with the above-described pattern or the like using a printing method such as screen printing.

Then, the reduction process is applied on the electrode formation regions 31zk and 41zk (FIG. 21(c)). The reduction process is a process to reduce the TCO at the electrode formation region 31zk exposed from an opening of the coating layer 50 and to form the protrusions 31p. When the TCO is reduced, at an initial stage of reduction, an amount of oxygen in the TCO is reduced and the sheet resistance is reduced, but in the present process, the TCO is further reduced. With such a configuration, for example, the sheet resistance becomes higher than that before the reduction, and the electrode formation region 31z in which the protrusions 31p are formed and the surface roughness is increased is obtained. In addition, in the region where the reduction process is applied, for example, a structure change from the columnar crystal layer to the non-columnar crystal layer can be observed. When the TCO is indium oxide (In₂O₃), protrusions 31p in which the proportion of indium (In) is increased are formed. In other words, the present process is a process to execute the reduction process until the protrusions 31p are formed and the surface roughness of the processed region becomes greater than the surface roughness in the non-processed region. In the present process, protrusions similar to the protrusions 31p are formed in the electrode formation region 41z exposed from an opening of the coating layer 51.

The method of the reduction process is not particularly limited so long as the TCO can be reduced and the protrusions can be formed, and for example, reduction by a hydrogen plasma process or electrolysis reduction maybe employed. The former is a gaseous phase reduction and the latter is a liquid phase reduction. The reduction process steps will now be described exemplifying the electrolysis reduction.

In the electrolysis reduction, for example, ammonium sulfate solution is used as an electrolytic solution, the photoelectric conversion unit 20 is set as a cathode, and a platinum plate is set as an anode. The photoelectric conversion unit 20 and the platinum plate are immersed in the electrolytic solution, and a current is applied between the photoelectric conversion unit 20 and the platinum plate. In this process, for example, a reduction terminal 100 connected to a negative electrode of a power supply device is attached to the photoelectric conversion unit 20, at a part over the exposed electrode formation region 31zk (refer to FIG. 22).

In the example configuration shown in FIG. 22, the reduction terminal 100 is attached to the electrode formation region 31zk (region R) positioned at the light receiving surface. Because the reduction of the TCO tends to occur more easily near the reduction terminal 100, in this case, the extent of reduction would be stronger in the region R1 than in the electrode formation region 31zk positioned at a center section of the light receiving surface (regions R2 and R3). With such a configuration, the surface roughness in the region R1 becomes greater than surface roughness in the regions R2 and R3. On the other hand, in the electrode formation region 41zk, because the entire region other than the region S1 is covered by the coating layer 51, the TCO is selectively reduced only at the region S1. With this configuration, the protrusions are formed only in the region S1, and the surface roughness becomes greater in the region S1 than in the regions S2 and S3. In other words, by changing the attachment position of the reduction terminal 100 and the mask pattern, the extent of the reduction of the TCO in the electrode formation region, that is, the extent of the surface roughness, can be easily changed. In addition, normally, as the amount of the applied current (current×time) is increased, the reduction of the TCO further progresses, and the surface roughness becomes greater.

The reduction terminal 100 is preferably attached, in the region R1, to regions corresponding to the finger portion 32 and the bus bar portion 33. In other words, the reduction terminal 100 is preferably attached to regions corresponding to ends in the longitudinal direction of the finger portion 32 and the bus bar portion 33. Because the number of bus bar portions 33 is small, the reduction terminals 100 can be attached to all regions corresponding to the ends in the longitudinal direction (for example, 4 locations). On the other hand, as the number of the finger portions 32 is large, for example, the reduction terminals 100 may be attached to only a part of the finger portions 32 with a predetermined spacing therebetween.

After the reduction process is completed, the coating layer 51 is removed, and the entire region over the electrode formation region 41z is exposed (FIG. 21(d)). The coating layer 51 can be removed using a known etchant. In the contrary, as the coating layer 50 is used as a mask in the plating process, the coating layer 50 is not removed. The coating layers 50 and 51 may be formed using resin compositions that are different from each other. For example, the coating layer 50 is formed using a resin composition which is not etched by the etchant used in the present process.

Then, the plated electrodes are formed directly over the electrode formation regions 31z and 41z (FIG. 21(e)). When the Cu plated electrode is to be formed, the electroplating is executed with the photoelectric conversion unit 20 set as a cathode and a Cu plate set as an anode. For example, after the electroplating terminal connected to a negative electrode of a power supply device is attached to an electrode formation region of the photoelectric conversion unit 20, the photoelectric conversion unit 20 and the Cu plate are immersed in a plating solution, and a current is applied between the photoelectric conversion unit 20 and the Cu plate. For the plating solution, a known copper plating solution containing copper sulfate or copper cyanide may be used. In this manner, a solar cell 11 is obtained in which the Cu plated electrode is formed over the electrode formation region including a region where the protrusions are formed and the surface roughness is increased. A thickness of the plated layer is preferably about 30 μm˜50 μm at the finger portion 32 and the bus bar portion 33, and is preferably about 0.5 μm˜10 μm at the metal layer 42. The thicknesses can be adjusted by adjusting an amount of applied current.

FIG. 23(a) is a plan view showing a mask pattern when the protrusions 31p are to be formed only in the region R1 (refer to FIG. 15). FIGS. 23(b)˜(d) are cross sectional diagrams along a longitudinal direction of the electrode formation region 31z, and the processes from a step of forming the mask pattern and applying the reduction process to the formation step of the plated electrode (finger portion 32) are shown.

The reduction process is executed using a coating layer 52 formed covering regions other than the region R1 over the transparent conductive layer 31 as a mask (FIG. 23(a)). With this step, only the TCO in the region R1 which is not covered by the coating layer 52 and which is exposed is selectively reduced, and the protrusions 31p are formed only in the region R1 (FIG. 23(b)). After the reduction process is completed, a part of the coating layer 52 is removed and the entire region of the electrode formation region 31z is exposed (FIG. 23(c)). In other words, the coating layer 50 is formed from the coating layer 52. By applying the plating process in this state, the plated electrode can be formed over the entire region of the electrode formation region 31z including the region R1.

FIG. 24 is a cross sectional diagram showing formation of the plated electrode by electroplating. In the example configuration of FIG. 24, an electroplating probe 110 having a plurality of electroplating terminals 111 is attached over the transparent conductive layer 41 and the electroplating process is executed. With this method, for example, the metal layer 42 can be formed covering approximately the entire region over the transparent conductive layer 41 while leaving a part of the region over the transparent conductive layer 41 corresponding to an area in which the wiring member 15 is attached. In other words, the metal layer 42 having a plurality of through holes 43 can be formed.

The plurality of electroplating terminals 111 are placed in a line form with a spacing therebetween, and a resin 112 is provided around each terminal. When this structure is attached over the transparent conductive layer 41, the plurality of electroplating terminals 111 are aligned in a line form. When the photoelectric conversion unit 20 is immersed in a plating solution 113 in this state, the plating solution 113 enters the region between the resins 112. With this process, the plated electrode can be formed over approximately the entire region, of the surface of the transparent conductive layer 41, for example, except for the region around the electroplating terminals 111 in which the plating solution 113 does not act. At the periphery of the electroplating terminals 111, through holes 43 are formed (refer to FIG. 18). In order to form the through holes 43 in the area in which the wiring member 15 is attached, for example, the plurality of electroplating terminals 111 are placed along the area.

The metal layer 42 having the through hole 43 or the bus bar portion 33 including the plurality of blocks 33p can also be formed using a mask pattern protecting the portions corresponding to the through hole 43 or the gap 34. More specifically, by applying a plating process using, as a mask, the coating layer 50 which exposes only the region, over the transparent conductive layer 31, in which the finger portion 32 and the plurality of blocks 33p are formed, it is possible to form the bus bar portion 33 including the plurality of blocks 33p.

As described, in the solar cell 11, by forming the Ag or Cu plated electrode having a superior reflection characteristic directly over the transparent conductive layers 31 and 41, an amount of reflection and attenuation of light entering the photoelectric conversion unit 20 can be inhibited and the light collecting efficiency can be improved. For example, by using a plated electrode having a single layer structure of Cu, in comparison to a case where a plated electrode having a layered structure of a Ni seed layer and a Cu layer is used, the reflection characteristic, in particular in the long wavelength region, can be improved, and the light collection efficiency can be improved.

The solar cell 11 has a greater surface roughness in at least a part of the electrode formation regions 31z and 41z, and the contact properties between the transparent conductive layers 31 and 41 and the collecting electrode are superior. Because of this, for example, even when the Cu plated electrode is formed directly over the transparent conductive layer 31 without the use of a Ni seed layer, a sufficient contact strength can be maintained.

In addition, the reduction process is applied in a limited manner in the regions where the contact strength between the collecting electrode and the transparent conductive layers 31 and 41 is particularly desired and the surface roughness is locally set greater. Because of this, for example, the contact strength can be efficiently improved without reducing the FF and the reflectance.

Moreover, because the through hole 43 is formed in the area of the metal layer 42 in which the wiring member 15 is attached, the adhesive 16 may enter the through hole 43, and adheres the wiring member 15 and the transparent conductive layer 41. With this configuration, the contact strength between the wiring member 15 and the solar cell 11 can be improved, and a solar cell module 10 with a high reliability can be obtained.

### EXPLANATION OF REFERENCE NUMERALS

10 Solar Cell Module; 11 Solar Cell; 12 First Protection Member; 13 Second Protection Member; 14 Encapsulant; 15 Wiring Member; 16 Adhesive; 20 Photoelectric Conversion Unit; 20z End Edge; 21 Substrate; 22, 23 Amorphous Semiconductor Layer; 31, 41 Transparent Conductive Layer; 31z, 41z Electrode Formation Region; 32 Finger Portion; 33 Bus Bar Portion; 34 Gap; 42 Metal Layer; 43 Through Hole; 50 Coating Layer.

1. A solar cell comprising:
a photoelectric conversion unit;
a transparent conductive layer formed over a primary surface of the photoelectric conversion unit; and
a silver or copper plated electrode formed directly over the transparent conductive layer.

2. The solar cell according to claim 1, wherein
the transparent conductive layer has a greater surface roughness at least in a part of an electrode formation region over which the plated electrode is formed, than in a region outside of the electrode formation region.

3. The solar cell according to claim 2, wherein
the transparent conductive layer has a greater surface roughness in a region, of an electrode formation region over which the plated electrode is formed, positioned at an end edge of the primary surface, than in a region positioned at a center section of the primary surface.

4. The solar cell according to claim 2, wherein
the transparent conductive layer has a greater surface roughness in a region, of an electrode formation region over which the plated electrode is formed, positioned at an end in a longitudinal direction of the plated electrode, than in a region positioned at a center section in the longitudinal direction of the plated electrode.

5. The solar cell according to claim 2, wherein
the transparent conductive layer has a greater roughness in at least one of a region corresponding to an area, of an electrode formation region over which the plated electrode is formed, where a wiring member to be connected to another solar cell is attached and a region positioned at an end edge of the primary surface, than in other regions.

6. The solar cell according to any one of claim 2, wherein
the plated electrode includes a metal layer formed over approximately an entire region over the transparent conductive layer, and
the metal layer has a through hole formed in an area where a wiring member is attached.

7. The solar cell according to any one of claim 2, wherein
the plated electrode includes a finger portion and a bus bar portion to which a wiring member is attached, and
the bus bar portion is formed by a plurality of portions arranged in a line form, and a gap is formed between the plurality of portions.

8. A solar cell module comprising:
a plurality of the solar cells according to claim 6;
a wiring member that connects the solar cells; and
an adhesive that adheres the plated electrode of the solar cell and the wiring member, and that enters into the through hole in the plated electrode and adheres the wiring member and the transparent conductive layer.

9. A solar cell module comprising:
a plurality of the solar cells according to claim 7;
a wiring member that connects the solar cells; and
an adhesive that adheres the plated electrode of the solar cell and the wiring member, and that enters into the gap in the plated electrode and adheres the wiring member and the transparent conductive layer.

10. A method of manufacturing a solar cell, comprising:
forming a transparent conductive layer over a primary surface of a photoelectric conversion unit; and
after applying a reduction process to at least a part of an electrode formation region, of a region over the transparent conducive layer, in which a silver or copper plated electrode is formed, forming the plated electrode in the electrode formation region.

11. The manufacturing method of claim 10, wherein
the reduction process is executed in a state in which a mask pattern covering over the transparent conductive layer is formed, and
the mask pattern exposes at least a part of the electrode formation region.

12. The manufacturing method according to claim 11, wherein
the mask pattern is formed to cover a part of the electrode formation region, and
a plating process for forming the plated electrode is executed in a state where a part of the mask pattern is removed after the reduction process and an entire region of the electrode formation region is exposed.

13. The manufacturing method according to claim 10, wherein
the reduction process is executed only on the electrode formation region positioned at an end edge of the primary surface or executed such that an extent of reduction is higher in the electrode formation region positioned at the end edge of the primary surface than in the electrode formation region positioned at a center section of the primary surface.

14. The manufacturing method according to claim 11, wherein
the reduction process is executed only on the electrode formation region positioned at an end edge of the primary surface or executed such that an extent of reduction is higher in the electrode formation region positioned at the end edge of the primary surface than in the electrode formation region positioned at a center section of the primary surface.

15. The manufacturing method according to claim 12, wherein
the reduction process is executed only on the electrode formation region positioned at an end edge of the primary surface or executed such that an extent of reduction is higher in the electrode formation region positioned at the end edge of the primary surface than in the electrode formation region positioned at a center section of the primary surface.

16. The manufacturing method according to claim 13, wherein
the reduction process is executed by attaching a reduction terminal at the electrode formation region positioned at the end edge of the primary surface and using an electrolysis reduction method.

17. The manufacturing method according to claim 10, wherein
the plated electrode includes a metal layer formed covering approximately an entire region over the transparent conductive layer, and
the metal layer is formed to cover approximately the entire region over the transparent conductive layer, while leaving a part of a region over the transparent conductive layer corresponding to an area where a wiring member is attached.

18. The manufacturing method according to claim 11, wherein
the plated electrode includes a metal layer formed covering approximately an entire region over the transparent conductive layer, and
the metal layer is formed to cover approximately the entire region over the transparent conductive layer, while leaving a part of a region over the transparent conductive layer corresponding to an area where a wiring member is attached.

19. The manufacturing method according to claim 12, wherein
the plated electrode includes a metal layer formed covering approximately an entire region over the transparent conductive layer, and
the metal layer is formed to cover approximately the entire region over the transparent conductive layer, while leaving a part of a region over the transparent conductive layer corresponding to an area where a wiring member is attached.

20. The manufacturing method according to claim 10, wherein
a plating process for forming the plated electrode is executed by arranging a plurality of electroplating terminals in a line form, attaching the plurality of electroplating terminals over the transparent conductive layer, and applying electroplating.
